(19) United States
(12) Patent Application Publication
(10) Pub. No.: US 2015/0200686 A1
(43) Pub. Date: Jul. 16, 2015

(54) ENCODING DEVICE, DECODING DEVICE, AND OPERATING METHOD THEREOF

(71) Applicants: SK HYNIX INC., Icheon (KR); Korea Advanced Institute of Science and Technology, Daejeon (KR)

(72) Inventors: Dae-Sung KIM, Gwangju (KR); Jeong-Seok HA, Daejeon (KR); Chol-Su CHAE, Icheon (KR); Seok-Jin JOO, Seoul (KR); Sang-Chul LEE, Yongin (KR)

(21) Appl. No.: 14/504,293

(22) Filed: Oct. 1, 2014

(30) Foreign Application Priority Data
Jan. 14, 2014 (KR) 10-2014-0004690

(51) Int. Cl. H03M 13/29; H03M 13/00

(52) U.S. Cl. CPC H03M 13/2906; H03M 13/616

(57) ABSTRACT

An encoding device includes a first encoder that generates a message matrix including a plurality of message blocks and a parity block having parity information of the plurality of message blocks, and a second encoder that adds row parity information and column parity information to the message matrix.

The present application claims priority under 35 U.S.C. §119(a) to Korean patent application number 10-2014-0004690, filed on Jan. 14, 2014, in the Korean Intellectual Property Office, which is incorporated herein by reference in its entirety as set forth in full.

### BACKGROUND

1. Technical Field

The present disclosure relates to an encoding device, a decoding device, and an operation method thereof. Particularly, embodiments of the present disclosure relate to an encoding device, a decoding device, and an operation method thereof, in which a message matrix including a plurality of message blocks and a parity block for the message blocks is generated, and an error of a message block having the error is corrected using the parity block during decoding of the message matrix.

2. Related Art

For error detection and correction, various block-based coding technologies are used, and a concatenation Bose-Chaudhuri-Hocquenghem (BCH) code technology is a representative example thereof.

In general, in a coding technology having a matrix of blocks and row and column parities for protecting the blocks, a (1,1) error pattern, where decoding failure occurs at one row parity, one column parity and one message block, has a large influence on an error floor. Such a (1,1) error pattern may indicate an error block having an error, but the coding technology may not provide information sufficient to determine a bit of the error block at which the error has occurred.

To this end, in a prior art for detecting and correcting errors in data read from a memory device, a corresponding memory area is read several times while changing a threshold value in order to determine the reliability of individual bits, and correct data is estimated using a decision result. However, such a prior art may cause the read performance of the memory device to deteriorate due to a plurality of read and check operations.

### SUMMARY

Embodiments of the present disclosure are directed to an encoding device, a decoding device, and operation methods thereof, by which it is possible to quickly correct a (1,1) error pattern that is a main cause of an error floor without passing through a plurality of read and check operations.

In one embodiment of the present disclosure, an encoding device includes: a first encoder that generates a message matrix from a plurality of message blocks and a parity block having a first parity information of the plurality of message blocks; and a second encoder that adds a second parity parity information to the message matrix.

In another embodiment, a decoding device includes: an error detector that decodes a message matrix including a plurality of message blocks and a parity block, and parity information of the message matrix, and detects an error message block having an error in the message matrix; and an error corrector that corrects the error of the error message block from the plurality of message blocks and s the parity block.

In another embodiment, an encoding method includes: a first step of receiving a message, and generating a message matrix including a plurality of message blocks and a parity block having a first parity information of the plurality of message blocks; and a second step of adding a second parity information to the message matrix.

In another embodiment, a decoding method includes: an error detection step of decoding a message matrix including a plurality of message blocks and a parity block, and an encoded is message including parity information of the message matrix, and detecting an error message block having an error in the message matrix; and an error correction step of correcting the error of the error message block from the plurality of message blocks and the parity block.

According to the present technology, it is possible to quickly correct a (1,1) error pattern that is a main cause of an error floor without performing a plurality of read and check operations, and thus to improve the performance of a memory device or a communication device employing the corresponding technology.

### BRIEF DESCRIPTION OF THE DRAWINGS

Features, aspects, and embodiments are described in conjunction with the attached drawings, in which:

FIG. 1 is a diagram illustrating a message matrix according to an embodiment of the present disclosure;

FIG. 2 and FIG. 3 are diagrams illustrating a message matrix according to another embodiment;

FIG. 4 is a block diagram of an encoding device according to an embodiment;

FIG. 5 is a flowchart illustrating an encoding method according to an embodiment;

FIG. 6 is a block diagram of a decoding device according to an embodiment;

FIG. 7 is a flowchart illustrating a decoding method is according to an embodiment; and

FIG. 8 is a graph illustrating an effect of an embodiment.

### DETAILED DESCRIPTION

Hereinafter, an encoding device, a decoding device, and operation methods thereof according to the present disclosure will be described in detail with reference to the accompanying drawings through an illustrative embodiment.

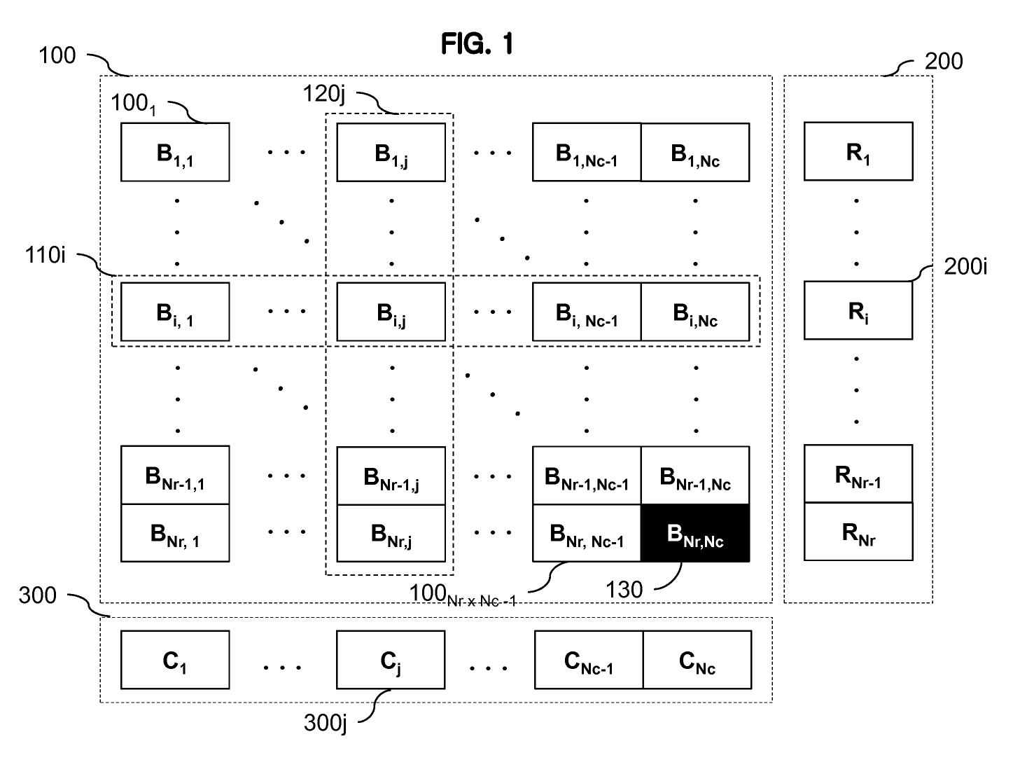

FIG. 1 is a diagram illustrating the structure of a message matrix 100 according to an embodiment of the present disclosure.

FIG. 1 is a diagram illustrating an example in which a row parity 200 and a column parity 300 are concatenated in a parallel manner, wherein the row parity 200 and the column parity 300 are concatenated to a message matrix 100 after the message matrix 100 is generated.

The message matrix 100 includes a plurality of row message blocks 110ᵢ and a plurality of column message blocks 120ⱼ, wherein, for a number of rows Nr and a number of columns Nc, i=1 . . . Nr and j=1 . . . Nc. A row message block 110ᵢ includes a plurality of message blocks arranged along a row i, and a column message block 120ⱼ includes a plurality of message blocks arranged along a column j. Thus, a specific message block Bᵢⱼ is located at an intersection of the row i and the column j. The message block B_{i,j} in the message matrix 100 may be protected by one row parity block 200ᵢ and one column parity block 300ⱼ.

Hereinafter, embodiments of the present disclosure are not dependent on a detailed code technology for generating a row or column parity block. For example, the row or column parity block may also be generated by applying a BCH code, a Hamming code, or a Reed-Solomon (RS) code, or may also be generated by applying another type of code technology.

The present disclosure is related to the structure of the message matrix 100 before a row or column parity is added. The message matrix 100 according to the present disclosure includes a plurality of message blocks 100ₖ and a parity block 130 including parity information of the plurality of message blocks 100ₖ (1≦k≦M−1 and M=Nr×Nc).

The parity block 130 may include single parity information of the plurality of message blocks 100ₖ. FIG. 1 illustrates that the parity block 130 exists in the last block position of the message matrix 100, but the position of the parity block 130 may be variously changed in the message matrix 100.

The message matrix 100 according to the embodiment of the present disclosure is designed in consideration of the lengths of the message blocks 100ₖ and the length of the parity block 130.

For example, when all of the plurality of message blocks 100ₖ include N (N is a natural number) bits, the parity block 130 may also be set to include N bits. An n^{th} bit (0≦n≦N−1) of the parity block 130 may be decided by performing an XOR operation on respective n^{th} bits of the message blocks 100ₖ.

If the lengths of the message blocks 100ₖ are different from one another and the maximum length among the lengths of the plurality of message blocks 100ₖ is N, the length of the parity block 130 may be set to N. In this case, the n^{th} bit (0≦n≦N−1) of the parity block 130 may be decided by performing an XOR operation on the respective n^{th} bits of the message blocks 100ₖ. If there is no n^{th} bit in one of the message blocks 100ₖ, a corresponding bit may be assumed to 0.

For example, when an error having a (1,1) pattern occurs in an i^{th} row and a j^{th} column in the process of decoding data concatenated in the parallel manner illustrated in FIG. 1, it can be determined that an error bit exists in the message block B_{i,j}.

In order to correct the error of the message block B_{i,j}, the information of the parity block 130 may be used. For example, the n^{th} bit of the message block B_{i,j} may be corrected by performing an XOR operation on n^{th} bits of the other message blocks 100ₖ, except for the message block having an error, and an n^{th} bit of the parity block 130. That is, the bits of the error message block B_{i,j} are reconstructed using the normal message blocks and the parity block 130, wherein the normal message blocks includes all of the message blocks 100ₖ except for the error message block B_{i,j}. In other embodiments, the value of an n^{th} bit of the message block B_{i,j} having the error may be indirectly corrected by performing an XOR operation on n^{th} bits of all the message blocks 100k and by comparing the result with the n^{th} bit of the parity block 130.

In this way, when an error due to the (1,1) error pattern is corrected, because it is not necessary to check the reliability of each bit's information, a plurality of memory read operations may be omitted.

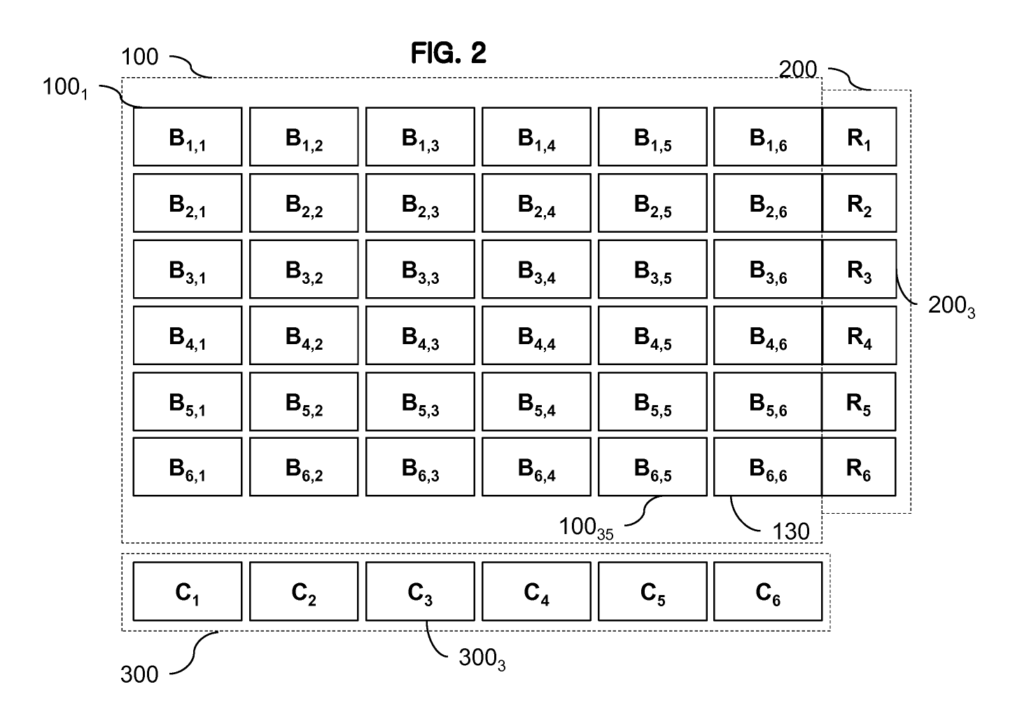

FIG. 2 is a diagram illustrating an example in which a row parity 200 and a column parity 300 are concatenated in a serial manner, wherein the row parity 200 and the column parity 300 are concatenated to a message matrix 100 after the message matrix 100 is generated from a message.

FIG. 2 illustrates an example of the message matrix 100 in which the number of rows is 6 and the number of columns is 6. Similarly to FIG. 1, the message matrix 100 includes a plurality of message blocks 100ₖ and a parity block 130 including parity information of the plurality of message blocks 100ₖ. The generation process for and the position of the parity block 130 are as described above.

Similarly to the case of the parallel concatenation, in the serial concatenation, a row parity block 200ᵢ is also generated in correspondence with each row of the message matrix 100. A column parity block 300ⱼ is generated for the message matrix 100 and the entire row parity 200.

In the serial concatenation according to the present embodiment, each row parity block Rᵢ is coupled to a corresponding message block B_{i,6} of one column of the message matrix 100.

FIG. 2 illustrates an embodiment in which a row parity block is coupled to a message block positioned in a sixth column of each row. That is, when generating the column parity 200, a row parity block R₁ is included in the message block B_{i,6} and a row parity block R₆ is included in a parity block 130 (B_{6,6}).

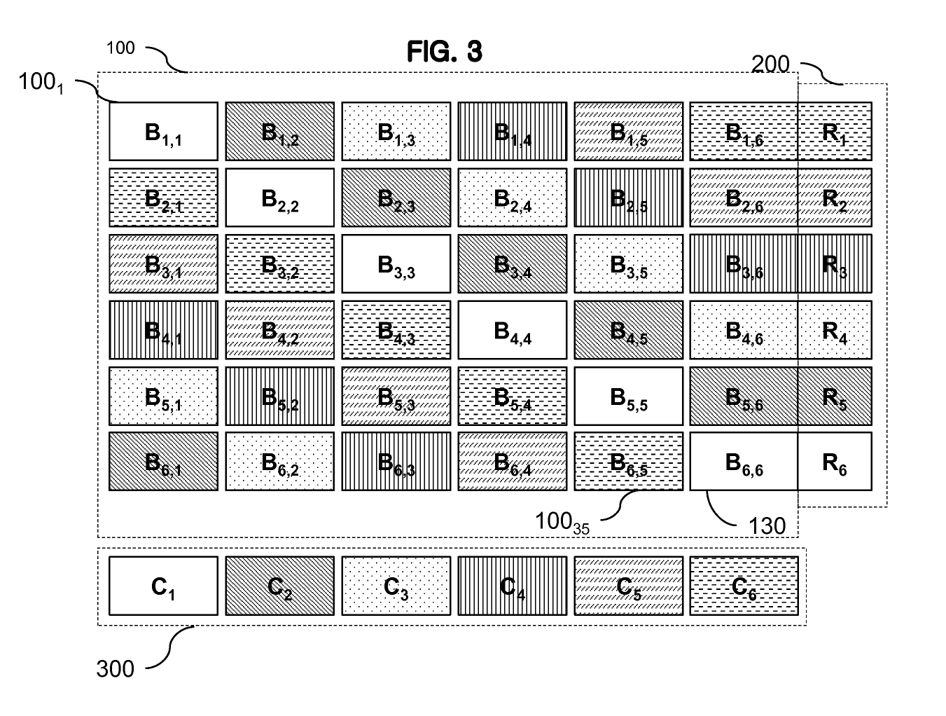

In this case, since the sixth column is longer than the first through fifth columns, it may not be preferable to generate a column parity block for each of the columns. In an embodiment, the columns of the message matrix 100 are rearranged in order to generate the column parity 300. An example of a schema for rearranging the columns of the message matrix 100 is illustrated in FIG. 3.

In FIG. 3, a column parity block and message blocks used to generate the column parity block are indicated by the same pattern.

In FIG. 3, a relation among a j^{th} column parity block Cⱼ, message blocks used to generate the column parity block Cⱼ, and a row parity block is expressed by Equation 1 below.

Cⱼ=[B_{1,f(j)}B_{2,f(j-1)} . . . B_{N,f(j-30 N}_{_{c}}₋₁₎R_{f(j+N}_{_{c}}₋₁₎], where f(x)={(x−1)modN_{c}}+1 Equation 1

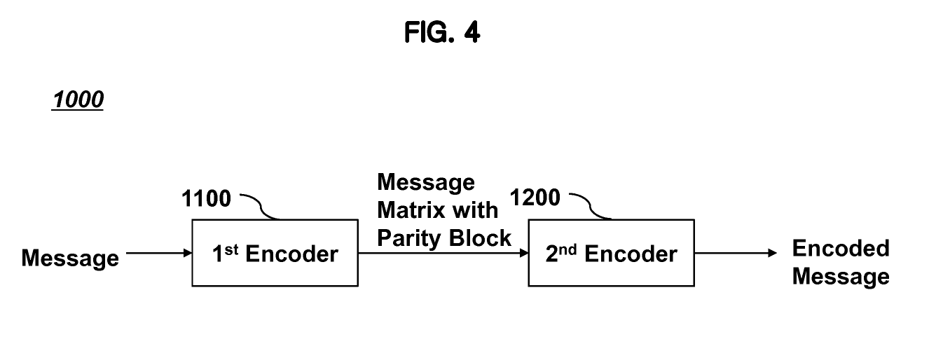

FIG. 4 is a block diagram illustrating an encoding device 1000 according to an embodiment of the present disclosure. The encoding device 1000 includes a first encoder 1100 and a second encoder 1200.

The first encoder 1100 generates a message matrix 100, in which a plurality of message blocks 100ₖ are arranged in a lattice form, from a message, wherein the message matrix 100 further includes a parity block 130 including parity information of the message blocks 100ₖ.

The first encoder 1100 may generate the message matrix 100 in consideration of the length of the message and the length of the parity block 130. The message blocks 100ₖ and the parity block 130 included in the message matrix 100 may have the same length or not.

Once the number of rows and the number of columns of the message matrix 100 have been determined, processes for distributing and arranging bits included in a message input with or without zero padding into the message blocks 100ₖ are known to those skilled in s the art from the prior art.

In the present disclosure, one block of the message matrix 100 is set as the parity block 130. The parity block 130 stores parity information of the other message blocks 100ₖ.

Since an embodiment of a process of generating the parity block 130 has been described with reference to FIG. 1, a detailed description thereof will be omitted. A person of skill in the art in light of the teachings and disclosure herein would understand how to implement the process of generating the parity block 130 in the first encoder 1100 by using a digital electronic circuit, or a processor is executing computer programming instructions stored on non-transitory computer-readable media, or a combination of both.

The second encoder 1200 adds a row parity 200 and a column parity 300 to the message matrix 100 including the message blocks 100ₖ and the parity block 130, and outputs an encoded message. A person of skill in the art in light of the teachings and disclosure herein would understand how to implement the second encoder 1100 by using a digital electronic circuit, or a processor executing computer programming instructions stored on non-transitory computer-readable media, or a combination of both.

The row parity 200 and the column parity 300 may be used for error detection and error correction in a decoding process. In order to generate the row parity 200 and the column parity 300, various code technologies may be applied.

For example, a code technology of a BCH code, an RS code, a Hamming code or the like may be applied to generate a row parity block and/or a column parity block, and the row parity block and the column parity block may be added to the message matrix 100, so that an encoded message may be output.

The encoded message may be written in a cell array of a memory device or may be transmitted through a communication channel.

In the process of adding the row parity 200 and the column parity 300 to the message matrix 100, the second encoder 1200 may is use a parallel concatenation scheme or a serial concatenation scheme. Since the parallel concatenation and the serial concatenation have been described with reference to FIG. 1 and FIG. 3, respectively, a detailed description thereof will be omitted.

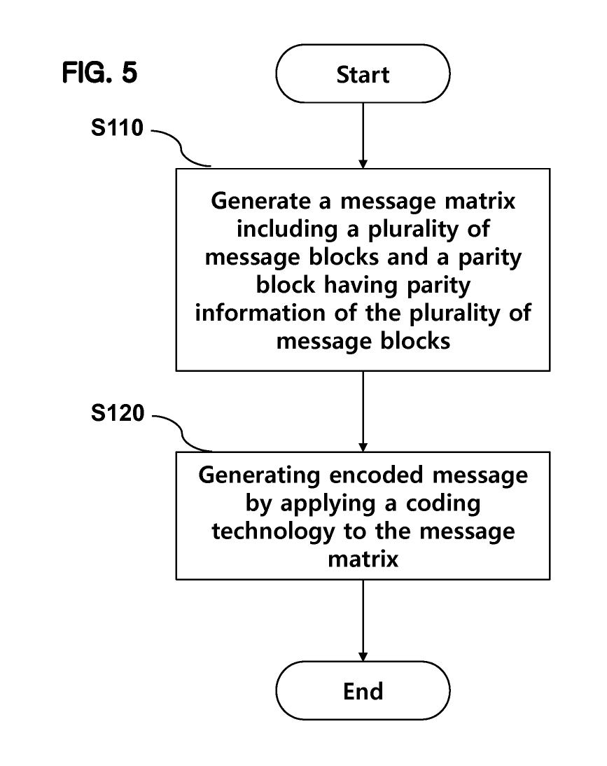

FIG. 5 is a flowchart illustrating an encoding process according to an embodiment of the present disclosure.

The encoding process according to the embodiment includes step S110 of generating a message matrix including a plurality of message blocks and a parity block having parity information of the plurality of message blocks from a message, and step S120 of generating a row parity and a column parity by applying a coding technology, such as a BCH code, an RS code, a Hamming code, or the like, to the message matrix.

Since step S110 corresponds to the operation of the first s encoder 1100 of FIG. 4 and step S120 corresponds to the operation of the second encoder 1200 of FIG. 4, a detailed description thereof will be omitted.

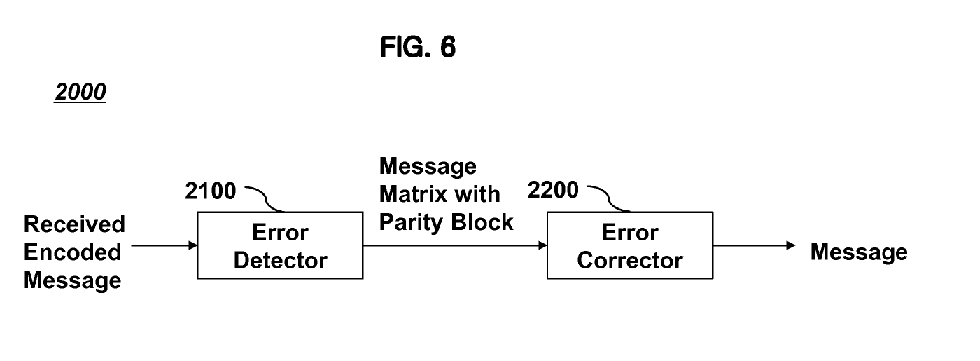

FIG. 6 is a block diagram of a decoding device 2000 according to the embodiment of the present disclosure.

The decoding device 2000 according to the embodiment includes an error detector 2100 and an error corrector 2200.

The error detector 2100 detects an error existing in a message matrix 100 by using a row parity 200 and a column parity 300 obtained by decoding a received encoded message. For example, is when an error occurs in an i^{t”} row parity block 200ᵢ and a j^{th} column parity block 300ⱼ, the error detector 2100 detects that an error of a (1,1) pattern has occurred in the message block B_{i,j}. A person of skill in the art in light of the teachings and disclosure herein would understand how to implement the error detector 2100 by using a digital electronic circuit, or a processor executing computer programming instructions stored on non-transitory computer-readable media, or a combination of both.

When the error detector 2100 detects a message block having an error, the error corrector 2200 corrects the error of the message block having the error by using other message blocks and the parity block 130 of the message matrix 100.

When an error is detected, the error corrector 2200 checks whether the corresponding error is correctable, and corrects the error if the error is correctable. For example, when it is detected that an error pattern having occurred in the message block B_{i,j} is a (1,1) pattern, the error corrector 2200 corrects the error by using message blocks, except for the message block B_{i,j} having the error, and the parity block 130.

If the parity block 130 has a single parity check function for the message blocks 100ₖ, a value of an n^{th} bit of the message block B_{i,j} having the error may be directly corrected by performing an XOR operation on n^{th} bits of the other message blocks 100ₖ, except for the message block B_{i,j}, and an n^{th} bit of the parity block 130. In other embodiments, the value of an n^{th} bit of the message block B_{i,j} having the error may be indirectly corrected by performing an XOR operation on n^{th} bits of all the message blocks 100k and by comparing the result with the n^{th} bit of the parity block 130.

A person of skill in the art in light of the teachings and disclosure herein would understand how to implement the error corrector 2200 using a digital electronic circuit, or a processor executing computer programming instructions stored on non-transitory computer-readable media, or a combination of both.

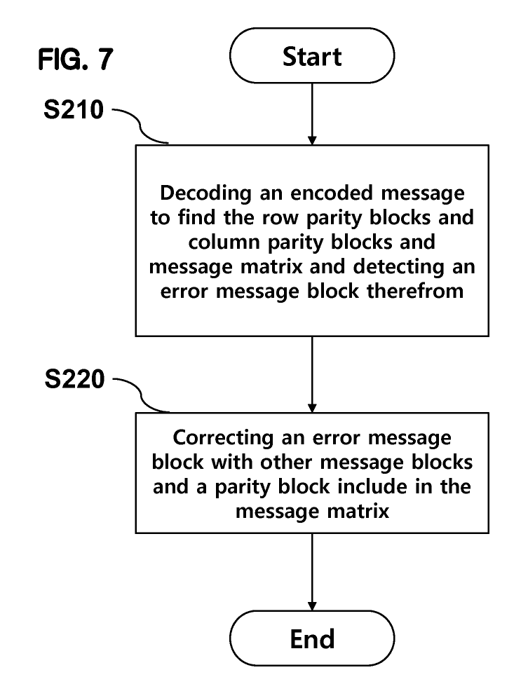

FIG. 7 is a flowchart illustrating a decoding process according to an embodiment of the present disclosure.

The decoding process according to the embodiment includes a step S210 of decoding an encoded message to obtain a message matrix and a row parity and a column parity for the message matrix, and detecting an error message block having an error in the message matrix by using the row parity and the column parity, and a step S220 of correcting the error message block by using other message blocks and parity blocks of the message matrix.

The step S210 of decoding the encoded message and detecting the error message block corresponds to the operation of the error detector 2100 of FIG. 6, and the step S220 of correcting the error of the error message block corresponds to the operation of the error corrector 2200 of FIG. 6. Since the error detector 2100 and the error corrector 2200 have been described in detail, a detailed description thereof will be omitted.

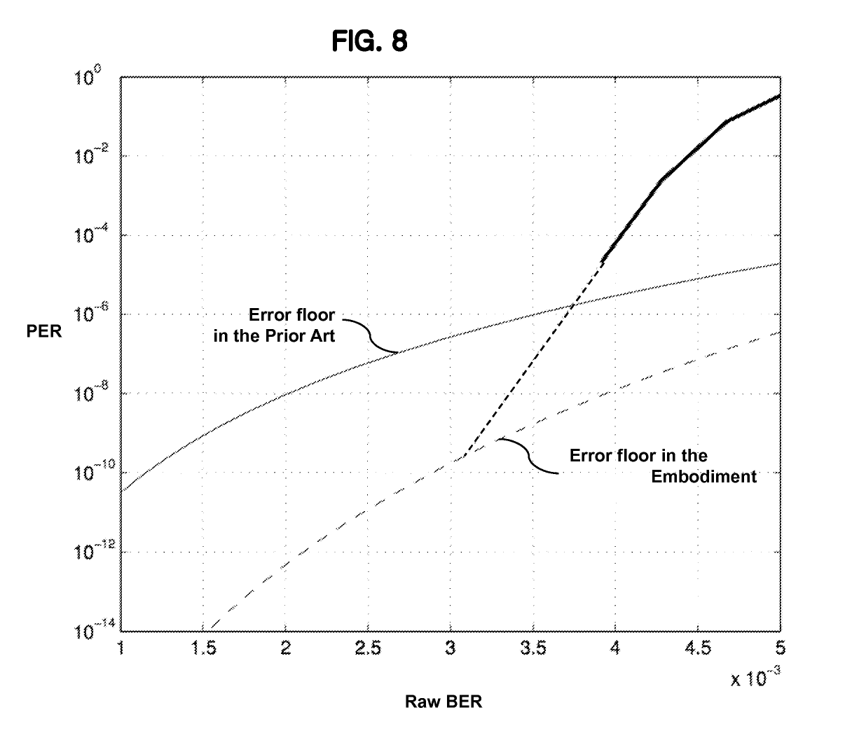

FIG. 8 is a graph illustrating an effect of an embodiment of the present disclosure.

The graph of FIG. 8 indicates experimental results using a BCH code technology of an irregular parallel concatenation scheme in which the lengths of message blocks are different from one another.

In the embodiment of the present disclosure, a parity block different from row and column parity blocks of the prior art is further added to a message, and the length of the added parity block is 57 bits.

In FIG. 8, in the case of the prior art and the present disclosure, a message length is a commonly used length of 65536 bits, the length of one message block 100ₖ is 56 bits or 57 bits, and the number of rows and the number of columns of the message matrix 100 are 34, respectively. Furthermore, the protection performance for each row of the message matrix is 6, the length of the row parity block 200ᵢ is 66, the protection performance for each column of the message matrix is 7, and the length of the column parity block 300ⱼ is 77.

The message matrix 100 having no parity block 130 according to the prior art is organized as 18 rows having a length of 1928 bits and 16 rows having a length of 1927 bits, and the message matrix 100 having the parity block 130 according to the present embodiment is organized as 7 rows having a length of 1930 bits and 27 rows having a length of 1929 bits.

In FIG. 8, a horizontal axis denotes a basic error rate of a memory cell as a single bit error rate (Raw BER), and a vertical axis denotes a page error rate (PER) after coding is applied. The graph of FIG. 8 shows that an error floor is significantly reduced by adding the parity block, as compared with the prior art.

For example, when the single bit error rate is 3×10⁻³, the page error rate in the embodiment is reduced to about 1/1000^{th} of the page error rate in the prior art. Consequently, it can be understood that the problem of the prior art, in which an error floor is not easily reduced due to the (1,1) error pattern, can be effectively solved through the present disclosure.

While certain embodiments have been described above, it will be understood to those skilled in the art that the embodiments described are by way of example only. Accordingly, the encoding device, decoding device, and operation methods thereof described herein should not be limited based on the described embodiments. Rather, the encoding device, decoding device, and operation methods thereof described herein should only be limited in light of the claims that follow when taken in conjunction with the above description and accompanying drawings.

What is claimed is:

1. An encoding device comprising:
a first encoder configured to generate a message matrix including a plurality of message blocks and a parity block having a first parity information of the plurality of message blocks; and
a second encoder that adds a second parity information to the message matrix.

2. The encoding device according to claim 1, wherein the parity block includes single parity information of the plurality of message blocks.

3. The encoding device according to claim 2, wherein the parity block includes a plurality of bits, wherein each of the plurality of bits is generated by operating on bits of corresponding positions in the plurality of message blocks.

4. The encoding device according to claim 3, wherein each of the plurality of bits is generated by performing an XOR operation on bits of corresponding positions in the plurality of message blocks.

5. The encoding device according to claim 1, wherein lengths of the plurality of message blocks are equal to a length of the parity block.

6. The encoding device according to claim 1, wherein lengths of at least a part of the plurality of message blocks are different from each other, and a length of the parity block is equal to a longest s length of lengths of the plurality of message blocks.

7. A decoding device comprising:
an error detector configured to decode an encoded message including a message matrix and parity information of the message matrix, and detect an error message block having an error in the message matrix, wherein the message matrix includes a plurality of message blocks and a parity block; and
an error corrector configured to correct the error of the error message block based on the plurality of message blocks and the parity block.

8. The decoding device according to claim 7, wherein the error detector detects the error message block using the parity information.

9. The decoding device according to claim 7, wherein the parity block includes single parity information of the plurality of message blocks.

10. The decoding device according to claim 9, wherein the error message block includes a plurality of bits, wherein each of the plurality of bits is corrected by operating on bits of corresponding positions of the plurality of message blocks and a corresponding bit of the parity block.

11. An encoding method comprising:
receiving a message;
generating a message matrix based on the message, the message matrix including a plurality of message blocks and a parity block including a first parity information of the plurality of message blocks; and
adding a second parity information to the message matrix.

12. The encoding method according to claim 11, wherein the generating step comprises:
distributing and arranging bits included in the message in the plurality of message blocks; and
deciding bits of the parity block from bits of the plurality of message blocks.

13. The encoding method according to claim 12, wherein lengths of the plurality of message blocks are equal to a length of the parity block.

14. The encoding method according to claim 12, wherein lengths of at least a part of the plurality of message blocks are different from each other, and a length of the parity block is equal to a longest length of lengths of the plurality of message blocks.

15. The encoding method according to claim 12, wherein each bit of the parity block performs a single parity check function for bits of corresponding positions of the plurality of message blocks.

16. The encoding method according to claim 15, wherein each bit of the parity block is decided by operating on the bits of the corresponding positions in the plurality of message blocks.

17. A decoding method comprising:
decoding an encoded message including a message matrix and parity information of the message matrix, wherein the message matrix includes a plurality of message blocks and a parity block;
detecting an error message block having an error in the message matrix; and
correcting the error of the error message block using the plurality of message blocks and the parity block.

18. The decoding method according to claim 17, wherein the detecting step comprises:
detecting the error message block using the parity information.

19. The decoding method according to claim 17, wherein the parity block includes single parity information of the plurality of message blocks.

20. The decoding method according to claim 19, wherein the correcting step comprises:
correcting corresponding bit information of the error message block by operating on bits of corresponding positions of the plurality of message blocks and a corresponding bit of the parity block.
